(19) United States
(12) Patent Application Publication
(10) Pub. No.: US 2022/0308462 A1
(43) Pub. Date: Sep. 29, 2022

(54) APPARATUS FOR PHOTORESIST DRY DEPOSITION

(71) Applicant: Lam Research Corporation, Fremont, CA (US)

(72) Inventors: Butch Berney, Pleasanton, CA (US); Alan M. Schoepp, Ben Lomond, CA 95005, CA (US); Timothy William Weidman, Sunnyvale, CA (US); Kevin Li Gu, Mountain View, CA (US); Chenghao Wu, Berkeley, CA (US); Katie Lynn Nardi, San Jose, CA (US); Boris Volosskiy, San Jose, CA (US); Clint Edward Thomas, Newark, CA (US); Thad Nicholson, San Jose, CA (US)

(21) Appl. No.: 17/596,928

(22) PCT Filed: Jun. 22, 2020
(86) PCT No.: PCT/US2020/038968

§ 371 Date: Dec. 21, 2021

Related U.S. Application Data
(60) Provisional application No. 62/867,428, filed on Jun. 27, 2019.

(51) Int. Cl. G03F 7/20

(52) U.S. Cl. CPC G03F 7/70858

(57) ABSTRACT

Systems and techniques for dry deposition of extreme ultra-violet-sensitive (EUV-sensitive) photoresist layers are discussed. In some such systems, a processing chamber may be provided that features a multi-plenum showerhead that is configured to receive a vaporized organometallic precursor in one plenum and a vaporized counter-reactant thereof in another plenum. The two vaporized reactants may be delivered to a reaction space within the processing chamber and over a wafer support that supports the substrate.

### RELATED APPLICATIONS

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

This disclosure relates generally to the field of semiconductor processing. In particular aspects, the disclosure is directed to hardware for dry deposition of EUV photoresists (e.g., EUV-sensitive metal and/or metal oxide-containing photoresists), for example, to form a patterning mask suited for use in EUV or other wavelength patterning. While discussion below may be focused on EUV photoresists, it will be apparent that the photoresists discussed herein may also be appropriate for use with other wavelengths of radiation and the techniques and apparatuses discussed herein are not limited solely to EUV photoresist manufacturing.

Reference is made herein in detail to specific embodiments of the disclosure Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

Patterning of thin films in semiconductor processing is often an important step in the fabrication of semiconductors. Patterning involves lithography. In conventional photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, which are on the lower end of the extreme ultraviolet spectrum of 124 nm to 10 nm, can be used for leading-edge lithography tools (also referred to as scanners). The EUV radiation is strongly absorbed in a wide range of solid and fluid materials including quartz and water vapor, and so operates in a vacuum.

### SUMMARY

Details of one or more implementations of the subject matter described in this specification are set forth in the accompanying drawings and the description below. Other features, aspects and advantages will become apparent from the description, the drawings and the claims.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts a cross-sectional schematic view of an example dry deposition apparatus for generating EUV-sensitive photoresist layers.

FIG. 2 depicts detail side section and plan views of a portion of a top plate, substrate, and edge ring.

FIG. 3 depicts a flow diagram of a process that includes a dry deposition process.

### DETAILED DESCRIPTION

EUV lithography makes use of EUV resists that are patterned to form masks for in etching underlying layers. EUV resists may be polymer-based chemically amplified resists (CARs) produced by liquid-based spin-on techniques. An alternative to CARs are directly photopatternable metal oxide-containing films, such as those available from Inpria Corporation, Corvallis, Oreg., and described, for example, in U.S. Pat. Pub. No. 2017/0102612, U.S. Pat. Pub. No. 2016/021660, and U.S. Pat. Pub. No. 2016/0116839, which are hereby incorporated by reference herein at least for their disclosure relating to photopatternable metal oxide-containing films. Such films may be produced by spin-on techniques or dry vapor-deposited.

Spin-on techniques, which are a form of a “wet” film formation technique, involve placing a flat substrate on a turntable, depositing an amount of liquid film constituent at the center of the substrate, and then rotating the substrate at a generally high speed, e.g., 20 to 80 rotations per second for 30 to 60 seconds, to produce a highly uniform thickness film. Dip-coating is another type of wet film formation technique in which the substrate is oriented with its major faces parallel to the vertical direction and then immersed in a bath of the liquid film constituent and then withdrawn. Due to the use of a liquid constituent, however, “wet” film formation techniques may not be well-suited for coating non-flat substrates, e.g., substrates with preexisting feature patterns etched in the exposed upper surface thereof. For example, if the substrate is not flat, e.g., has existing features patterned into the surface-to-be-coated, the liquid constituent will tend to fill those features, leading to a variable film thickness between non-featured portions of the substrate and featured portions of the substrate (while the uppermost surface of the deposited film may be nominally planar and uniform, the depths of the deposited film may vary with underlying feature presence).

Dry deposition techniques, also referred to as vapor deposition techniques, as well as other similar techniques, in contrast, deliver the film constituent to the substrate as a vapor-phase reactant, where it then condenses or adsorbs onto the exposed surface of the substrate in a generally conformal, even-thickness layer. As a result, the thickness of the deposited film layer may generally remain uniform across the substrate, regardless of whether in a featured or unfeatured region of the substrate. It is to be understood that such deposition techniques are not viewed as “wet” techniques even if, in some cases, there is condensation of the film constituent on the target substrate. Another key advantage to dry deposition processes such as are discussed herein is that such processes may be performed in a range of different temperature and pressure environments, and are often performed at sub-atmospheric conditions. This allows for much smaller amounts of the reactants to be used to produce a given photoresist film than would be necessary to produce an equivalent film using a wet deposition process. This reduces the material cost for providing such films over providing equivalent films using wet deposition techniques. Dry deposition processes also incur a lower throughput penalty, as the substrates that are produced are able to be prepared for subsequent processing phases at a greater rate since there is little or no need to dry the substrate after applying the photoresist layer.

The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018, and titled EUV PHOTOPATTERNING OF VAPOR-DEPOSITED METAL OXIDE-CONTAINING HARDMASKS, and/or in Intl. Pat. App. No. PCT/US19/31618, filed May 9, 2019, and titled METHODS FOR MAKING EUV PATTERNABLE HARD MASKS, the disclosures of which at least relating to the composition, deposition, and patterning of directly photopatternable metal oxide films to form EUV resist masks are hereby incorporated by reference herein. Generally, the patterning involves exposure of the EUV resist with EUV radiation to form a photo pattern in the resist, followed by development to remove a portion of the resist according to the photo pattern to form the mask. The mask may then be used in subsequent processing operations, e.g., etch processes

Directly photopatternable EUV resists may be composed of or contain metals and/or metal oxides mixed within organic components. The metals/metal oxide-containing materials are highly promising in that they can enhance the EUV photon adsorption and generate secondary electrons and/or show increased etch selectivity to an underlying film stack and device layers.

The EUV-sensitive metal or metal oxide-containing film may be dry-deposited on the substrate. Some characteristics of suitable compositions, materials and dry deposition processing operations in accordance with this disclosure are described in Intl. Pat. Appl. No. PCT/US19/31618, filed May 9, 2019, which is hereby incorporated herein by reference for the disclosure of these methods and materials applicable to the present disclosure. Such methods include those where polymerized organometallic materials are produced in the vapor phase and deposited on a substrate. In particular, methods for making EUV-patternable thin films on a surface of a semiconductor substrate may include: mixing a vapor stream of an organometallic precursor with a vapor stream of a counter-reactant so as to form a polymerized organometallic material; and depositing the organometallic polymer-like material onto the surface of the semiconductor substrate. In some embodiments, more than one organometallic precursor is included in the vapor stream. In some embodiments, more than one counter-reactant is included in the vapor stream. In some embodiments, the mixing and depositing operations are performed in a continuous chemical vapor deposition (CVD), an atomic layer deposition (ALD) process, or ALD with a CVD component, such as a discontinuous, ALD-like process in which metal precursors and counter-reactants are separated in either time or time and space, e.g., in some ALD-type processes, one or more organometallic precursors may be flowed onto a substrate and the substrate may then be moved to another processing station or to another processing chamber where one or more counter-reactants may be flowed onto the substrate. It will be understood that reference herein to simply “reactants” is intended to refer to both the organometallic precursor and the counter-reactant, e.g., “simultaneous flow of the reactants” would refer to simultaneous flow of the organometallic precursor and the counter-reactant.

Following deposition, the EUV-patternable thin film is patterned by exposing the wafer with the thin film to a beam of EUV light that is passed through an optical mask having features to be patterned on the wafer, typically under relatively high vacuum, and then removing the wafer from vacuum and optionally performing a post exposure bake in ambient air. The exposure results in one or more exposed regions, such that the film includes one or more unexposed regions that have not been exposed to EUV light. Further processing of the coated substrate may exploit chemical and physical differences in the exposed and unexposed regions.

Substrates may include any material construct suitable for photolithographic processing, particularly for the production of integrated circuits and other semiconductor-based devices. In some embodiments, such substrates may be silicon wafers. Substrates upon which features have been created (“underlying features”) may have an irregular surface topography (as referred to herein, the “surface” is a surface onto which a film of the present disclosure is to be deposited or that is to be exposed to EUV during processing). Such underlying features may include regions in which material has been removed (e.g., by etching) or regions in which materials have been added (e.g., by deposition) during processing prior to conducting a method of this disclosure. Such prior processing may include methods of this disclosure or other processing methods in an iterative process by which two or more layers of features are formed on the substrate.

As discussed earlier, EUV-sensitive thin films may be deposited on a substrate to create a mask layer. Such EUV-sensitive films may be operable as resists for subsequent EUV lithography and processing and may include materials which, upon exposure to EUV, undergo changes, such as the loss of bulky pendant substituents bonded to metal atoms in low density M-OH rich materials, that allow their crosslinking to denser M-O-M bonded metal oxide materials, where M is a metal with a high EUV absorption cross-section. Through EUV patterning, areas of the film are created that have altered physical or chemical properties relative to unexposed areas. These properties may be exploited in subsequent processing, such as to dissolve either unexposed or exposed areas, or to selectively deposit materials on either the exposed or unexposed areas. In some embodiments, the unexposed film has a more hydrophobic surface than the exposed film under the conditions at which such subsequent processing is performed. For example, the removal of material may be performed by leveraging differences in chemical composition, density and cross-linking of the film. Removal may be by wet processing or dry processing, as further described below.

The thin films are, in various embodiments, organometallic materials, for example organotin materials comprising SnOₓ, or other metal oxides materials/moieties. The organometallic compounds may be made in a vapor phase reaction of an organometallic precursor with a counter-reactant. In various embodiments, the organometallic compounds are formed through mixing specific combinations of organometallic precursors having bulky alkyl groups or fluoroalkyl with counter-reactants and polymerizing the mixture in the vapor phase to produce a low-density, EUV-sensitive material that deposits onto the substrate.

In various embodiments, organometallic precursors may include at least one alkyl group on each metal atom that can survive the vapor-phase reaction, while other ligands or ions coordinated to the metal atom can be replaced by the counter-reactants. Organometallic precursors include those of the formula MₐR_{b}L_{c} where M is a metal with a high EUV absorption cross-section; R is alkyl, such as CₙH₂ₙ₊₁, preferably wherein n≥3; L is a ligand, ion or other moiety which is reactive with the counter-reactant; a≥1; b≥1; and c≥1.

In various embodiments, M has an atomic absorption cross section equal to or greater than 1·10⁷ cm²/mol. M may be, for example, be a material such as tin, bismuth, antimony, tellurium, or combinations of two or more thereof. In some embodiments, M is tin. R may be fluorinated, e.g., having the formula CₙFₓH₂ₙ₊₁. In various embodiments, R has at least one beta-hydrogen or beta-fluorine. For example, R may be an i-propyl, n-propyl, t-butyl, i-butyl, n-butyl, sec-butyl, n-pentyl, i-pentyl, t-pentyl, sec-pentyl, or a mixture of two or more thereof. L may be any moiety readily displaced by a counter-reactant to generate an M-OH moiety, such as a moiety that is an amine (such as a dialkylamino or monalkylamino group), an alkoxy group, a carboxylate, a halogen, or mixtures of two or more thereof.

Organometallic precursors may be any of a wide variety of candidate metal-organic precursors. For example, where M is tin, such precursors include t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(diethylamino) tin, and analogous alkyl(tris)(t-butoxy) tin compounds such as t-butyl tris(t-butoxy) tin. In some embodiments, the organometallic precursors may be partially fluorinated.

Counter-reactants may be selected to have the ability to replace the reactive moieties, ligands or ions (e.g., L in Formula 1, above) so as to link at least two metal atoms via chemical bonding. Counter-reactants can include water, peroxides (e.g., hydrogen peroxide), di- or polyhydroxy alcohols, fluorinated di- or polyhydroxy alcohols, fluorinated glycols, and other sources of hydroxyl moieties. In various embodiments, a counter-reactant reacts with the organometallic precursor by forming oxygen bridges between neighboring metal atoms. Other potential counter-reactants include hydrogen sulfide and hydrogen disulfide, which can crosslink metal atoms via sulfur bridges.

The thin films may include optional materials in addition to an organometallic precursor and counter-reactants to modify the chemical or physical properties of the film, such as to modify the sensitivity of the film to EUV or to enhance etch resistance. Such optional materials may be introduced, for example, by doping during vapor phase formation prior to deposition of the film on the substrate, after deposition of the film, or both. In some embodiments, a gentle remote H₂ plasma may be introduced so as to replace some Sn-L bonds with Sn—H, which can increase reactivity of the resist under EUV.

In various embodiments, the EUV-patternable films may be deposited on the substrate using vapor deposition equipment and processes among those known in the art. In such processes, the polymerized organometallic material may be formed in vapor phase or in situ on the surface of the substrate. Suitable processes for forming such polymerized organometallic material on a substrate include, for example, depositing it using chemical vapor deposition (CVD), atomic layer deposition (ALD), or ALD with a CVD component, such as a discontinuous, ALD-like process in which metal precursors and counter-reactants are separated in either time or time and space.

In general, methods may include mixing a vapor stream of an organometallic precursor with a vapor stream of a counter-reactant so as to form a polymerized organometallic material, and then depositing the organometallic material onto the surface of the semiconductor substrate. As will be understood by one of ordinary skill in the art, the mixing and depositing aspects of the process may be concurrent, in a substantially continuous process.

In an exemplary continuous CVD process, two or more gas streams, in separate inlet paths, of organometallic precursor and source of counter-reactant may be introduced into a deposition chamber of a CVD apparatus, where they may mix and react in the gas phase to form agglomerated polymeric materials (e.g., via metal-oxygen-metal bond formation). The streams may be separately introduced into the deposition chamber, for example, using separate injection inlets or via a dual-plenum showerhead. The apparatus may be configured so that the flows of organometallic precursor and counter-reactant are mixed in the deposition chamber, allowing the organometallic precursor and counter-reactant to react to form the polymerized organometallic material. Without limiting the mechanism, function or utility of present technology, it is believed that the product from such vapor-phase reaction becomes heavier in molecular weight as metal atoms are crosslinked by counter-reactants, and is then condensed or otherwise deposited onto the substrate. In various embodiments, the steric hindrance of the bulky alkyl groups prevents the formation of densely packed networks and produces porous, low density films.

The CVD process is generally conducted at reduced pressures, such as from 10 milliTorr to 10 Torr. In some embodiments, the process is conducted at from 0.5 to 2 Torr. The temperature of the substrate may preferably be kept at or below the temperature of the reactant streams. For example, the substrate temperature may be from 0° C. to 250° C., or from ambient temperature (e.g., 23° C.) to 150° C. In various processes, deposition of the polymerized organometallic material on the substrate may occur at rates inversely proportional to surface temperature.

The thickness of the EUV-patternable film formed on the surface of the substrate may vary according to the surface characteristics, materials used, deposition duration, and processing conditions. In various embodiments, the film thickness may range from 0.5 nm to 100 nm and the overall absorption of the resist film may be 30% or less (e.g., 10% or less, or 5% or less) so that the resist material at the bottom of the resist film is sufficiently exposed. In some embodiments, the film thickness is from 10 to 20 nm. Without limiting the mechanism, function or utility of present disclosure, it is believed that, unlike wet, spin-coating processes of the art, the processes of the present disclosure have fewer restrictions on the surface adhesion properties of the substrate, and can therefore be applied to a wider variety of substrates. Moreover, as discussed above, the deposited films may closely conform to surface features, providing advantages in forming masks over substrates, such as substrates having underlying features, without “filling in” or otherwise planarizing such features.

The deposited film may be patterned by exposing one or more regions of the film to EUV light, e.g., using a scanner or other lithography photopattern transfer tool. EUV devices and imaging methods among those useful herein include methods known in the art. In particular, as discussed above, exposed areas of the film that are created through EUV patterning may have altered physical or chemical properties relative to unexposed areas of the film. For example, in exposed areas, metal-carbon bond cleavage may occur via beta-hydride elimination, leaving behind reactive and accessible metal hydride functionality that can be converted to hydroxide and cross-linked metal oxide moieties via metal-oxygen bridges, which can be used to create chemical contrast either as a negative tone resist or as a template for hard mask. In general, a greater number of beta-H in the alkyl group results in a more sensitive film. Following exposure, the film may be baked, e.g., at a temperature of 150 to 250° C., so as to cause additional cross-linking of the metal oxide film. The difference in properties between exposed and unexposed areas may be exploited in subsequent processing, such as to dissolve unexposed areas or to deposit materials on the exposed areas. For example, the pattern can be developed using a dry method to form a metal oxide-containing mask. Methods and apparatus among those useful in such processes are described in U.S. Patent Application 62/782,578, filed Dec. 20, 2018, which is hereby incorporated by reference herein for its disclosure of the methods and apparatus.

Such dry development processes can be done by using either a gentle plasma (high pressure, low power) or a thermal process, either of which may be performed while flowing a hydrogen halide dry development chemistry such as HBr or HCl. In some embodiments, the hydrogen halide is able to quickly remove the unexposed material, leaving behind a pattern of the exposed film that can then be transferred into the underlying substrate layers by subsequent application of plasma-based etch processes, for example conventional etch processes.

Suitable plasma-based dry development processes may include the use of transformer coupled plasma (TCP), inductively coupled plasma (ICP), or capacitively coupled plasma (CCP) processes, and may be implemented using equipment and techniques among those known in the art. For example, a plasma-based development process may be conducted at a pressure of >5 mT (e.g., >15 mT), at a power level of <1000 W (e.g., <500 W). Temperatures may be from 0 to 300° C. (e.g., 30 to 120° C.), at flow rate of 100 to 1000 standard cubic centimeters per minute (sccm), e.g., about 500 seem, for from 1 to 3000 seconds (e.g., 10-600 seconds).

In thermal development processes, the substrate may be exposed to dry development chemistry. Suitable chambers for performing such thermal development processes may include a vacuum line, one or more dry development chemistry gas lines to provide dry developments chemistry gases to the chamber, and heaters to allow for temperature control of the chamber. In some embodiments, the chamber interior may be coated with corrosion-resistant films, such as organic polymers or inorganic coatings. One such coating is polytetrafluoroethene ((PTFE), Teflon™). Such materials can be used in thermal processes of this disclosure, although such a coating may not be appropriate for plasma-based processes due to the risk of removal by plasma exposure.

Current EUV resist coating technology typically uses a spin-on photoresist which is applied in atmospheric environment, e.g., at typical atmospheric pressures. This technique does not generally allow for atmospheric control or influence and only allows only a single chemical mixture to be applied for the entire film stack. Spin-on techniques also do not provide for uniform photoresist layer thickness for substrates having non-planar surfaces on which the film is to be formed.

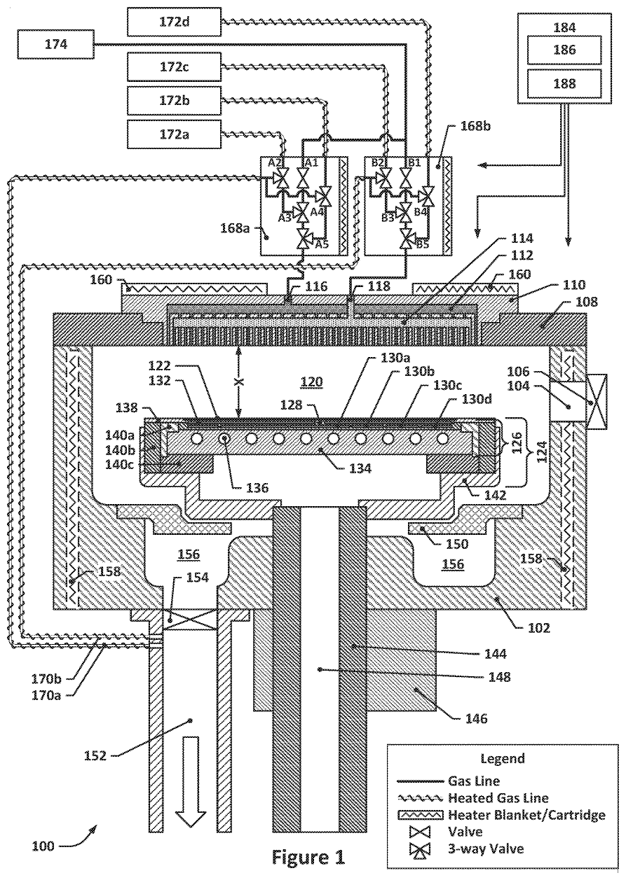

As mentioned earlier, dry deposition techniques may be used to create photoresist layers that do not suffer from the thickness non-uniformity issues that wet-deposited techniques suffer from with regard to substrates with pre-existing features. Such dry deposition techniques may be performed using a photoresist film deposition chamber. An example photoresist film deposition chamber is depicted in FIG. 1.

In FIG. 1, an apparatus 100 is depicted that has a processing chamber 102 that includes a lid 108. The processing chamber 102 may include a wafer transfer passage 104 through one of the walls of the processing chamber 102 that is sized to allow a substrate 122 to be passed therethrough and into the interior of the processing chamber 102, where the substrate 122 may be placed on a wafer support 124. The wafer transfer passage 104 may have a gate valve 106 or similar door mechanism that may be operated to seal or unseal the wafer transfer passage, thereby allowing the environment within the processing chamber 102 to be isolated from the environment on the other side of the gate valve 106. For example, the processing chamber 102 may be provided substrates 122 via a wafer handling robot that is located in an adjoining transfer chamber. Such a transfer chamber may, for example, have multiple processing chambers 102 arranged around its periphery, with each such processing chamber 102 connected with the transfer chamber via a corresponding gate valve 106.

The wafer support 124 may, for example, include an electrostatic chuck (ESC) 126, which may be used to provide a wafer support surface for supporting the substrate 122. The ESC 126 may include, for example, a base plate 134 that is bonded to a top plate 128 that is placed atop the base plate 134. The top plate 128 may, for example, be made of a ceramic material and may have embedded within it several other components. In the depicted example, the top plate 128 has two separate electrical systems embedded within it. One such system is an electrostatic clamping electrode system, which may have one or more clamping electrodes 132 that may be used to generate an electric charge within the substrate 122 that causes the substrate 122 to be drawn against the wafer support surface of the top plate 128. In the implementation of FIG. 1, there are two clamping electrodes 132 that provide a bi-polar electrostatic clamping system, although some implementations may use only a single clamping electrode 132 to provide a mono-polar electrostatic clamping system.

The other system is a thermal control system that may be used to control the temperature of the substrate 122 during processing conditions. In FIG. 1, the thermal control system is a multi-zone thermal control system featuring four annular resistance heater traces 130a, 130b, 130c, and 130d that are concentric with one another and positioned beneath the clamping electrodes 132. The center resistance heater traces 130a may, in some implementations, fill a generally circular area, and each resistance heater trace 130a/b/c/d may follow a generally serpentine or otherwise meandering path within a corresponding annular region. Each resistance heater trace 130a/b/c/d may be individually controlled to provide a variety of radial heating profiles in the top plate 128; such a four-zone heating system may, for example, be controlled to maintain the substrate 122 so as to have a temperature uniformity of ±0.5° C. in some cases. While the apparatus 100 of FIG. 1 features a four-zone heating system in the ESC 126, other implementations may use single-zone or multi-zone heating systems having more or fewer than four zones.

In some implementations, of, for example, temperature control mechanisms discussed above, heat pumps may be used instead of resistance heating traces. For example, in some implementations, the resistance heater traces may be replaced by, or augmented by, Peltier junctions or other, similar devices that may be controlled to “pump” heat from one side thereof to another. Such mechanisms may be used, for example, to draw heat from the top plate 128 (and thus the substrate 122) and direct it into the baseplate 134 and the heat exchange passages 136, thereby allowing the substrate 122 to be cooled more rapidly and more effectively, if desired.

The ESC 126 may also include, for example, a base plate 134 that may be used to provide structural support to the underside of the top plate 128 and which may also act as a heat dispersion system. For example, the base plate 134 may include one or more heat exchange passages 136 that are arranged in a generally distributed fashion throughout the base plate 134, e.g., the heat exchange passages 136 may follow a serpentine, circular switchback, or spiral pattern around the center of the base plate 134. A heat exchange medium, e.g., water or inert fluorinated liquid, may be circulated through the heat exchange passages 136 during use. The flow rate and temperature of the heat exchange medium may be externally controlled so as to result in a particular heating or cooling behavior in the base plate 134.

The ESC 126 may, for example, be supported by a wafer support housing 142 that is connected with, and supported by, a wafer support column 144. The wafer support column 144 may, for example, have a routing passage 148 other pass-throughs for routing cabling, fluid flow conduits, and other equipment to the underside of the base plate 134 and/or the top plate 128. For example, while not shown in FIG. 1, cabling for providing electrical power to the resistance heater traces 130a/b/c/d may be routed through the routing passage 148, as may cabling for providing electrical power to the clamping electrodes 132. Other cables, e.g., cables for temperature sensors, may also be routed through the routing passage 148 to locations in the interior of the wafer support 124. In implementations with a temperature-controllable base plate 134, conduits for conveying heat exchange medium to and from the base plate 134 may also be routed through the routing passage 148. To avoid undue clutter, such cables and conduits are not depicted in FIG. 1, but it is to be understood that they would, nonetheless, be present.

The apparatus 100 of FIG. 1 also includes a wafer support z-actuator 146 that may provide movable support to the wafer support column 144. The wafer support z-actuator 146 may be actuated to cause the wafer support column 144, and the wafer support 124 supported thereby, to move up or down vertically, e.g., by up to several inches, within a reaction space 120 of the processing chamber 102. In doing so, a gap distance X between the substrate 122 and the underside of the showerhead 110 may be tuned depending on various process conditions.

The wafer support 124 may also include, in some implementations, one or more edge rings that may be used to control and/or fine-tune various process conditions. In FIG. 1, an upper edge ring 138 is provided that lies on top of, for example, lower edge rings 140a and 140b, which, in turn, are supported by the wafer support housing 142 and a third lower edge ring 140c. The upper edge ring 138 may, for example, be generally subjected to the same processing environment as the substrate 122, whereas the lower edge rings 140a/b/c may generally be shielded from the processing environment. Due to the increased exposure of the upper edge ring 138, the upper edge ring 138 may have a limited lifespan and may require more frequent replacement or cleaning as compared with the lower edge rings 140a/b/c.

The apparatus 100 may also include a system for removing process gases from the processing chamber 102 during and after processing concludes. For example, the processing chamber 102 may include an annular plenum 156 that encircles the wafer support column 144. The annular plenum 156 may, in turn, be fluidically connected with a vacuum foreline 152 that may be connected with a vacuum pump, e.g., such as may be located beneath a subfloor below the apparatus 100. A regulator valve 154 may be provided in between the vacuum foreline 152 and the processing chamber 102 and actuated to control the flow into the vacuum foreline 152. In some implementations, a baffle 150, e.g., an annular plate or other structure that may serve to make the flow into the annular plenum 156 more evenly distributed about the circumference of the wafer support column 144, may be provided to reduce the chances of flow non-uniformities developing in reactants flowed across the substrate 122.

The showerhead 110, as shown, is a dual-plenum showerhead 110 and includes a first plenum 112 that is provided process gas via a first inlet 116 and a second plenum 114 that is provided process gas via a second inlet 118. The showerhead 110 may, in some implementations, have more than two plenums, although two plenums is generally the minimum required to maintain separation between the organometallic precursor and the counter-reactant prior to release of the organometallic precursor and the counter-reactant into the reaction space 120 of the processing chamber 102. Each plenum may have a corresponding set of gas distribution ports that fluidically connect the respective plenum with the reaction space 120 through the faceplate of the showerhead 110 (the faceplate being the portion of the showerhead 110 that is interposed between the lowermost plenum and the reaction space 120).

The first inlet 116 and the second inlet 118 of the showerhead 110 may be provided processing gases via a gas supply system, which may be configured to provide one or more organometallic precursors and one or more counter-reactants, as discussed earlier herein.

The depicted apparatus 100, however, is configured to provide multiple organometallic precursors and multiple counter-reactants. For example, a first valve manifold 168a may be configured to provide organometallic precursors to the first inlet 116, while a second valve manifold 168b may be configured to provide counter-reactants to the second inlet 118.

In this example, the first valve manifold 168a, for example, includes multiple valves A1-AS. Valve A2 may, for example, be a three-way valve that has one port fluidically connected with a first vaporizer 172a, another port fluidically connected with a bypass line 170a, and a third port fluidically connected with a port on another 3-way valve A3. Similarly, valve A4 may be another three-way valve that has one port fluidically connected with a second vaporizer 172b, another port fluidically connected with the bypass line 170a, and a third port fluidically connected with a port on another 3-way valve A5. One of the other ports on valve A5 may be fluidically connected with the first inlet 116 while the remaining port on valve A5 may be fluidically connected with one of the remaining ports on the valve A3. The remaining port on the valve A3 may, in turn, be fluidically connected with the valve A1 which may be fluidically interposed between the valve A3 and a purge gas source 174, e.g., nitrogen, argon, or other suitably inert gas (with respect to the organometallic precursor and/or the counter-reactant).

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

The first valve manifold 168a may, for example, be controllable to cause vapors from one or both of the vaporizers 172a and 172b to be flowed either to the processing chamber 102 or through the first bypass line 170a and into the vacuum foreline 152. The first valve manifold 168a may also be controllable to cause a purge gas to be flowed from the purge gas source 174 and into the first inlet 116.

For example, to flow vapor from the first vaporizer 172a into the reaction space 120, the valve A2 may be actuated to cause the vapor from the first vaporizer 172a to first flow into the first bypass line 170a. This flow may be maintained for a period of time sufficient to allow the flow of the vapor to reach steady state flow conditions. After sufficient time has passed (or after a flow meter, if used, indicates that the flow rate is stable), valves A2, A3, and A5 may be actuated to cause the vapor flow from the first vaporizer 172a to be directed to the first inlet. Similar operations with valves A4 and A5 may be performed to deliver vapor from the second vaporizer 172b to the first inlet 116. In some instances, it may be desirable to purge one of the vapors from the first plenum 112 by actuating the valves A1, A3, and AS so as to cause the purge gas from the purge gas source 174 to be flowed into the first inlet 116. In some additional implementations, it may be desirable to simultaneously flow vapor from one of the vaporizers 172a or 172b in tandem with flowing gas from the purge gas into the first inlet 116. Such implementations may be used to dilute the concentration of the reactant(s) contained in such vapor(s).

It will be appreciated that the second valve manifold 168b may be controlled in a similar manner, e.g., by controlling valves B1-BS, to provide vapors from vaporizers 172c and 172d to the second inlet 118 or to the second bypass line 170b. It will be further appreciated that different manifold arrangements may be utilized as well, including a single unitary manifold that includes valves for controlling flow of both organometallic precursor(s) and counter-reactant(s) to the first inlet 116 and the second inlet 118.

As mentioned earlier, some apparatuses 100 may feature a lesser number of vapor sources, e.g., only two vaporizers 172, in which case the valve manifold(s) 168 may be modified to have a lesser number of valves, e.g., only valves A1-A3.

As discussed above, apparatuses such as apparatus 100, which may be used to provide for dry deposition of photoresist films using organometallic precursors and counter-reactants, may be configured to maintain particular temperature profiles within the processing chamber 102. In particular, such apparatuses 100 may be configured to maintain the substrate 122 at a lower temperature, e.g., at least 25° C. to 50° lower, than most of the equipment of the apparatus 102 that comes into direct contact with the organometallic precursor(s) and the counter-reactant(s). Additionally, the temperature of the equipment of the apparatus 100 that comes into direct contact with the organometallic precursor(s) and the counter-reactant(s) may be kept to an elevated level that is sufficiently high that condensation of the vaporized reactants on the surfaces of such equipment is discouraged. At the same time, the substrate 122 temperature may be controlled to a level that promotes condensation, or at least deposition, of the reactants on the substrate 122.

To provide for such temperature control, various heating systems may be included in the apparatus 100. For example, the processing chamber 102 may have receptacles for receiving cartridge heaters 158, e.g., for a processing chamber 102 that has a generally cylindrical interior volume but a square or rectangular external shape, vertical holes for receiving cartridge heaters 158 may be bored into the four corners of the chamber 102 housing. In some implementations, the showerhead 110 may be covered with heater blankets 160, which may be used to apply heat across the exposed upper surface of the showerhead 110 to keep the showerhead temperature elevated. It may also be beneficial to heat various gas lines that are used to conduct the vaporized reactants from the vaporizers 172 to the showerhead 110. For example, resistive heater tape may be wound around such gas lines and used to heat them to an elevated temperature. As shown in FIG. 1, all of the gas lines that potentially have either an organometallic precursor or a counter-reactant flowing through them are shown as being heated, including the bypass lines 170. The only exceptions are the gas lines from the valve manifolds 168 to the first inlet 116 and the second inlet 118, which may be quite short and may be indirectly heated by the showerhead 110. Of course, even these gas lines may be actively heated, if desired. In some implementations, heaters may be provided proximate to the gate valve 106 to provide heat to the gate valve as well.

The various operational systems of the apparatus 100 may be controlled by a controller 184, which may include one or more processors 186 and one or more memory devices 188 that are operatively connected with each other and that are communicatively connected with various systems and subsystems of the apparatus 100 so as to provide for control functionality for those systems. For example, the controller 184 may be configured to control the valves A1-AS and B1-BS, the various heaters 158, 160, the vaporizers 172, the regulator valve 154, the gate valve 106, the wafer support z-actuator, and so forth.

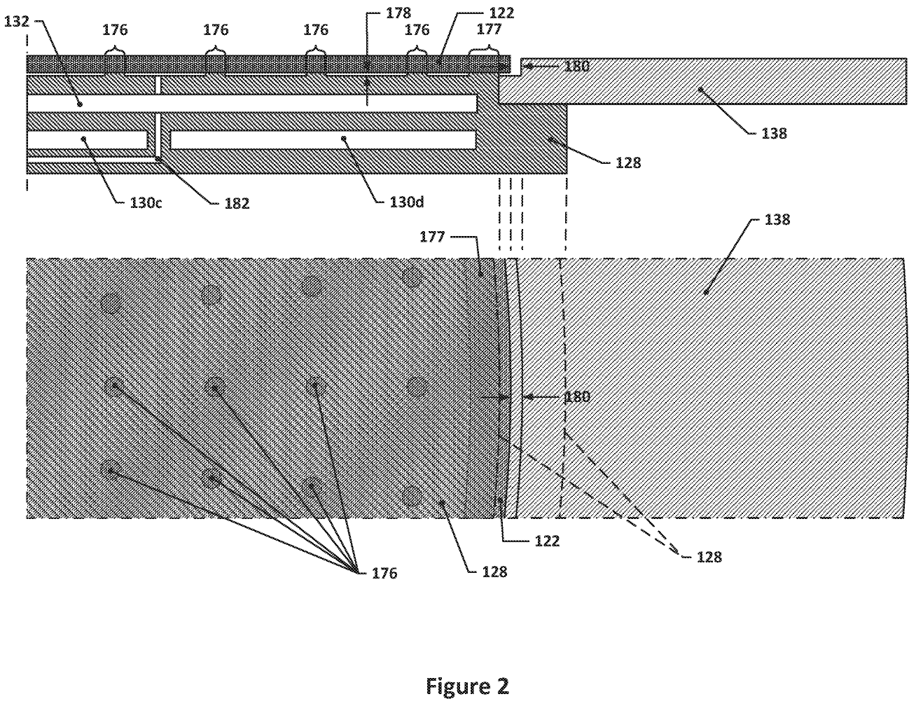

Another feature that the apparatus 100 may include is shown in FIG. 2, which depicts close-up side cross-sectional and plan views of a portion of the substrate 122, top plate 128, and upper edge ring 138 of FIG. 1. As can be seen, in some implementations, the substrate 122 may be elevated off of most of the top plate 128 by a plurality of small mesas 176, which may be shallow bosses that protrude from the nominal upper surface of the top plate 128 by a small distance so as to provide for a backside gap 178 between the underside of the substrate 122 and the majority of the top plate 128. A circumferential wall feature 177 may be provided at the periphery of the top plate 128. The circumferential wall feature 177 may extend around the entire perimeter of the top plate 128 and be of nominally the same height as the mesas 176. During processing operations, a generally inert gas, such as helium, may be flowed into the backside gap 178 via one or more gas ports 182. This gas may then flow radially outward before encountering the circumferential wall feature 177, which way then restrict such radially outward flow and cause a higher-pressure region of the gas to be trapped between the substrate 122 and the top plate 128. The inert gas that leaks past the circumferential wall 177 may eventually flow out through a radial gap 180 between the outer edge of the substrate 122 and a portion of the upper edge ring 138. Such gas may serve to protect the underside of the substrate from undesirably being affected by the processing operations being performed by acting to prevent the gases released by the showerhead 110 from reaching the underside of the substrate 122. At the same time, the gas released into the backside gap 178 region may also act to increase thermal coupling between the substrate 122 and the top plate 128, thereby allowing the top plate 128 to more effectively heat or cool the substrate 122. Due to the higher pressure provided by the circumferential wall, the gas that is within the backside gap 178 region may also be at a higher density than gas in the remainder of the chamber, and may thus provide more effective thermal coupling between the substrate 122 and the top plate 128.

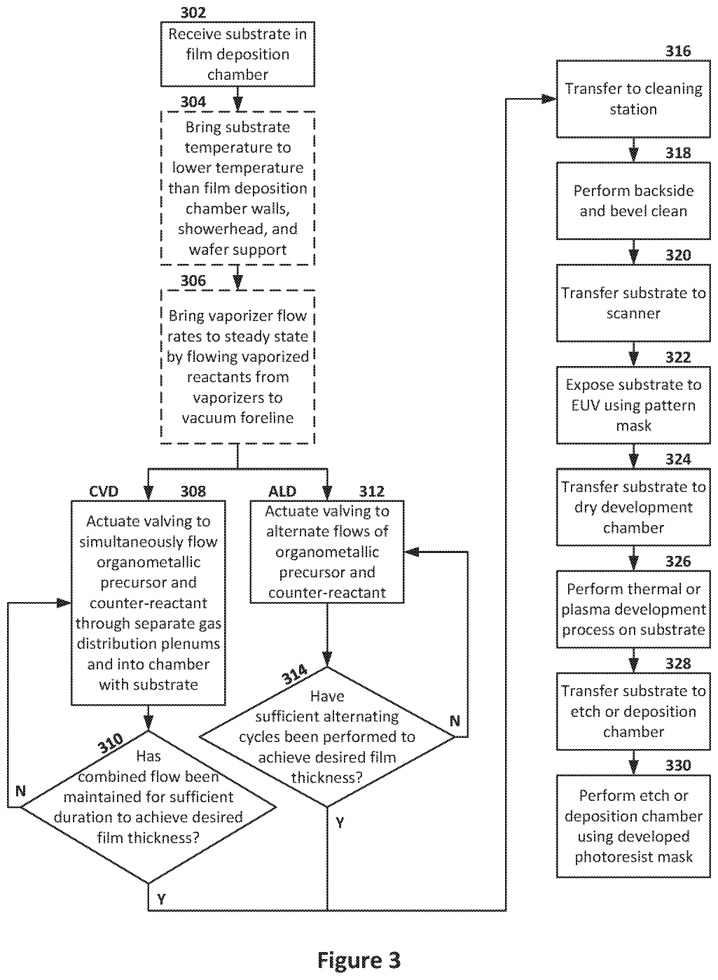

The controller 184 may be configured, e.g., via execution of computer-executable instructions, to cause the apparatus 100 to perform various operations consistent with the disclosure provided above. FIG. 3 depicts a flow diagram of various operations that may be performed in the context of the apparatus 100, as well as subsequent operations that may be performed on a substrate processed in the apparatus 100.

In block 302, for example, the controller 184 may control the apparatus 100 to cause the substrate 122 to be provided to, and placed in, the processing chamber 102. For example, a wafer handling robot may be controlled (or requested) to cause the substrate 122 to be passed through the wafer transfer passage 104 while the gate valve 106 is controlled to be actuated into an open state. The wafer support 124 may, for example, be controlled to be positioned, via the wafer support i-actuator 146, at an appropriate elevation to receive the substrate 122, which may be positioned above (and centered over) the wafer support 124 by the wafer handling robot. Lift pins (not shown) that are part of the wafer support 124 may be caused to be vertically extended from the wafer support 124 to lift the substrate off of an end effector of the wafer handling robot, allowing the wafer handling robot to be retracted from the processing chamber 102 and for the gate valve 106 to be closed, thereby sealing the processing chamber 102. At the same time, the lift pins may be retracted into the wafer support 124 to lower the substrate 122 onto the top plate 128.

Once the substrate 122 has been loaded in block 302, the resistance heater traces 130a/b/c/d may be controlled, along with the temperature and the flow rate of the heat exchange medium circulated through the base plate 134, to cause the substrate 122 to reach a desired temperature in block 304. Such control may also include, for example, activating the clamping electrode(s) to provide electrostatic clamping of the substrate 122 to the top plate 128 and to provide inert gas flow to the gas ports 182 of the top plate 128 to flow such gas into the backside gap 178 between the substrate 122 and the top plate 128. For example, the controller 184 may control the various heater systems of the apparatus 100 to maintain the temperature of the interior wall surfaces of the processing chamber 102, the lid 108, and the showerhead 110 to between 80° C. and 120° C., e.g., 100° C. At the same time, the controller 184 may control the top plate 128 so as to cause the top plate 128 and the substrate 122 to reach and maintain a temperature of between 55° C. and 75° C., e.g., 65° C. Other temperature ranges may be used as well, although the temperature of the top plate 128 and substrate 122 may be generally kept to a lower level than the remainder of the chamber so as to promote vapor adsorption and/or condensation on the substrate 122 over adsorption and/or condensation on the remaining chamber components.

In block 306, gas flow from the vaporizers 172 supplying the gas to be used in the dry deposition process may be initiated and allowed to reach steady state, e.g., by causing the valves A1-AS and B1-BS to be selectively actuated so as to divert the gas flows from those vaporizers 172 to the bypass lines 170 and into the vacuum foreline 152. Once the flow rates from the selected vaporizers have reached steady state, the technique may then proceed to either block 308 or block 312.

Blocks 308 and 312 represent two alternative approaches to dry-depositing an EUV-sensitive photoresist on the substrate 122. It will be understood that either approach may be used, as appropriate, in the alternative. In the approach of block 308, the controller may be configured to cause an organometallic precursor and a corresponding counter-reactant to be simultaneously dispensed from their respective vaporizers 172 and through respective plenums of the showerhead 110 into the reaction space 120 for a given duration of time. In block 310, a determination may be made if the desired duration of organometallic precursor and corresponding counter-reactant has elapsed (or if the desired amounts of such reactants have been dispensed). If not, then the technique may return to block 308 for further reactant dispensation. If so, then the technique may proceed to block 316, in which the substrate 122 may be removed from the processing chamber 102 and transferred to, for example, a cleaning station or other apparatus. It will be understood that the dry deposition process, at least with respect to the EUV-sensitive photoresist layer deposited in blocks 308 and 310, is essentially complete prior to removal of the substrate 122 from the processing chamber 102. Subsequent portions of the technique of FIG. 3 may occur in other equipment and/or be directed by other controllers if necessary. The technique of blocks 308 and 310 may be referred to as a continuous CVD technique, as the reactants are all flowed simultaneously into the reaction space 120 for a given duration or for a given amount, much as in a CVD process.

In the alternative approach of block 312, the valving of the apparatus 100 may be actuated to alternate flows of the organometallic precursor and the corresponding counter-reactant, e.g, first flow the organometallic precursor through the showerhead 110 and then stop the flow of the organometallic precursor and start the flow of the counter-reactant through the showerhead 110. In some implementations, a purge gas may be flowed through the showerhead 110 in between each reactant flow. These alternating flows may be repeated, if desired, one or more times. For example, in block 314, a determination may be made as to whether the desired number of alternating flow cycles has been performed; if not, then the technique may return to block 312 for performance of a further such flow cycle. If so, then the technique may proceed to block 316. This alternative approach is somewhat similar to atomic layer deposition techniques, in which two different precursors are alternatingly flowed into a deposition chamber. As with the previous simultaneous flow technique, at the conclusion of the alternating flow technique, i.e., after block 314 and prior to block 316, the dry deposition process, at least with respect to the EUV-sensitive photoresist layer deposited in blocks 312 and 314, is essentially complete prior to removal of the substrate 122 from the processing chamber 102.

It will be understood that various permutations and variations of such techniques may be practiced. For example, in some implementations, different organometallic precursors and/or counter-reactants may be used during different stages of an EUV-sensitive photoresist layer deposition process. In one such example, a first organometallic precursor with greater EUV sensitivity may initially be flowed across the substrate to create a first sub-layer of the EUV-sensitive photoresist layer. A second organometallic precursor (different from the first) may then be flowed across the substrate to create a second sub-layer on top of the first sub-layer. This process may be repeated for any number of different organometallic precursors (and/or counter-reactants). Such arrangements may allow the EUV sensitive photoresist layer to be a hybrid of different types of materials. If desired, organometallic precursors may be selected so as to produce sub-layers that have different EUV sensitivities—for example, the first sub-layer may be made using an organometallic precursor that creates a sub-layer that has a greater EUV sensitivity than that of the second sub-layer. This may help, for example, offset potential gradient effects when the deposited EUV-sensitive photoresist film is subjected to EUV exposure. For example, when the deposited EUV-sensitive photoresist film is exposed to EUV light, such light may cause physical or chemical changes in the exposed areas of the photoresist film that can then be leveraged in a post-exposure process, e.g., a developer process. However, such physical or chemical changes may be dependent on the intensity of the EUV radiation. Since the EUV radiation tends to decrease in intensity as a function of increasing penetration depth into the photoresist film due to absorption of some of the energy by upper sub-layers of the photoresist film, the exposure intensity for the lower sub-layer(s) in the photoresist film may be less than in the upper sub-layer(s). As a result, in photoresist films that are made of the same material throughout their entire thickness, the amount of physical or chemical change that is generated through the EUV exposure process may vary as a function of film depth. In some such instances, the duration of such exposure may also affect this variation.

However, by tailoring the photoresist film to utilize different materials for different sub-layers, it may be possible to reduce the variation in physical or chemical change that occurs throughout the thickness of the photosensitive film. For example, if a lower sub-layer is made of a material that is more sensitive to EUV exposure than an upper sub-layer, then this may help compensate for the reduced EUV exposure intensity experienced by that lower sub-layer.

It will be appreciated that such tailoring techniques may have significant benefits in the context of EUV processing, both in terms of throughput and quality. For example, in order to expose the lowest sublayer(s) of a single-material photoresist film to an amount of EUV sufficient to cause the desired level of chemical or physical change in that/those sub-layer(s), it may be necessary to continue to expose the photosensitive film for a much longer period of time than is required to achieve the same level of chemical of physical change in the upper sub-layer(s). This additional exposure time could, for example, be used to perform EUV exposure on another substrate, i.e., results in decreased throughput. Given the extreme cost of EUV processing equipment (an EUV scanner, for example, can cost on the order of $100 million+ (US)), minimizing processing time for EUV scanning operations is highly desirable in order to maximize the return on the investment made into the EUV scanner).

Longer exposure times may also result in decreased quality in the photopattern that is transferred to the photosensitive film through the EUV exposure process. For the nanometer-scale feature sizes that require resort to EUV processing, even the smallest movements of the EUV mask (the mask through which the EUV light is directed in order to produce the desired photopattern on the substrate 122) relative to the substrate 122 can be significant in terms of feature size. For example, for a feature of 30 nm width, a 5 nm shift in the EUV mask relative to the substrate 122 during the exposure process can result in a ^{˜}15% decrease in full depth feature width. While EUV scanners are designed to minimize the potential for such occurrences, the longer the exposure process takes for a given substrate 122, the larger the risk is of such movements being encountered (or, more likely, the larger the risk is of encountering more lower-magnitude movements that, in aggregate, have an increased negative effect than the movements do individually).

It will be readily apparent that tailoring the material makeup of such photoresist films using the techniques discussed herein may, for example, allow for reduced exposure times that increase throughput and increase the likelihood of obtaining higher-quality photopatterns. The conformal nature of dry-deposited photoresist films also contributes towards achieving such throughput improvements, as the relatively uniform film thickness avoids scenarios where variations in total film thickness result that require increased EUV exposure time.

As noted earlier, wet deposition of such EUV-sensitive photoresist films are generally not suitable for tailored film deposition since it is not possible to use different materials for different sub-layers of wet-deposited EUV-sensitive photoresist films. Moreover, wet deposition techniques are not conformal in nature. The dry-deposition techniques and equipment discussed herein thus provide significant improvements over wet-deposition techniques and equipment using similar chemistries.

Another example of a dry-deposition technique that may be practiced with the above-described apparatus is one in which different organometallic sub-layers are deposited on the substrate 122 using different dry deposition processes. For example, the technique of blocks 312 and 314 may be used to deposit a thin sub-layer of a first EUV-sensitive photoresist material on the substrate 122 that may, for example, enhance the adsorption or condensation of reactants used to produce a subsequently applied sub-layer of a second, different EUV-sensitive photoresist material. In this sense, the first photoresist material may be used as a “seed sub-layer” to enhance adhesion of the second photoresist material. In such implementations, it may be preferable to use the technique of blocks 312 and 314, which may be more easily controlled to produce thinner sub-layers, for the seed sub-layer, and to then switch to the technique of blocks 308 and 310, which may provide a higher, but not as finely controllable, deposition rate that may be used to provide a thicker sub-layer of the second EUV-sensitive photoresist.

Once the EUV-sensitive photoresist film has been deposited on the substrate 122, the substrate 122 may, as noted above, be transferred to one or more subsequent processing chambers or tool for additional operations. The remaining blocks of FIG. 3 summarize such additional operations for one such implementation, although other implementations may involve other operations or other orders of operations.

For example, subsequent to the completion of the dry deposition processes of blocks 308/310 and/or 312/314, the substrate 122 may be transferred to a cleaning station in block 316 which may be controlled to perform, for example, backside and/or bevel cleaning operations on the substrate 122 in block 318. Following such post-deposition cleaning, the substrate may then be transferred into an EUV scanner system or similar photolithography tool in block 320. In block 322, the EUV scanner may be controlled to apply a photopattern to the substrate using a pattern mask that causes various portions of the substrate 122 to be either exposed to EUV radiation or occluded from such exposure. The exposure process may be continued for as long as is necessary in order to achieve the desired degree of EUV exposure in the exposed regions of the photoresist film on the substrate 122.

After sufficient EUV exposure has been provided to the substrate 122 by the EUV scanner, the substrate 122 may be transferred to a dry development chamber in block 324 and then subjected to a dry development process, such as a thermal- or plasma-based development process. During such a development process, one or the other of the EUV-exposed portions of the substrate 122 and the non-exposed portions of the substrate 122 may be removed using a development process, e.g., dry development process as discussed earlier above, to produce the desired feature mask on the substrate 122.

After the feature mask has been created on the substrate 122, the substrate 122 may be removed from the dry development chamber and provided in block 328 to a process chamber, e.g., a deposition or etch chamber. A suitable semiconductor processing operation, e.g., an etch process or deposition process, may then be performed in block 330 using the feature mask that was provided using the patterns EUV-sensitive photoresist film.

In some implementations, the controller may be part of a larger system. Such systems may include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs) and/or one or more microprocessors, or microcontrollers that execute program instructions (e.g, software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

It will be generally understood that reference to “films,” “photoresist films,” “deposited layers,” “sub-layers,” and the like in the context of the dry deposition techniques discussed herein is intended to be inclusive of EUV-sensitive photoresist films, even if not explicitly indicated as such.

It will also be understood that the various components of the apparatus may be made a variety of suitable materials. For example, as discussed earlier, the top plate of the ESC may be made from a ceramic material, which may serve to electrically insulate the clamping electrodes embedded within (as well as the resistive heater elements embedded within) as well as to protect the base plate located underneath. The upper edge ring and the lower edge rings may similarly be made of a ceramic material, if desired. Other structures, such as the processing chamber itself, the showerhead, the base plate of the ESC, and the wafer support housing, may be made of a material such as an aluminum alloy, and may, in some instances, be anodized or otherwise coated with a protective coating. Materials such as aluminum are relatively inexpensive to machine, provide good chemical resistance when properly coated, and offer excellent heat conduction performance, allowing them to be easily heated to a desired operating temperature.

It should also be understood that the while present disclosure relates to lithographic patterning techniques and materials exemplified by EUV lithography, it is also applicable to other next-generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. The specific methods may depend on the particular materials and applications used in the semiconductor substrate and ultimate semiconducting device. Thus the methods described in this application are merely exemplary of the methods and materials that may be used in present technology.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise). It is also to be understood that the term “aggregate” may similarly be used to refer to a group of one as well as a plural group. Thus, for example, if there are one or more items that, in aggregate, include one or more sub-items, this is inclusive of a single item including a single sub-item, a single item including multiple sub-items, multiple items that each include a single sub-item, and multiple items that each include multiple subitems, as well as other permutations and combinations, e.g., hybrids of such examples.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus for providing photoresist films, the apparatus comprising:
a processing chamber,
a wafer support disposed within the processing chamber,
a showerhead positioned above the wafer support and configured to distribute gases flowed therethrough across the wafer support, wherein the showerhead includes a first plenum that is fluidically connected with a plurality of first gas distribution ports leading to a reaction space between the wafer support and the showerhead and a second plenum that is fluidically connected with a plurality of second gas distribution ports leading to the reaction space between the wafer support and the showerhead,
one or more valve manifolds having, in aggregate, one or more valves, and
a controller having one or more processors and one or more memory devices, wherein:
the one or more processors and the one or more memory devices are operably connected, and
the one or more memory devices store computer-executable instructions for controlling the one or more processors to:
a) cause at least a first valve of the one or more valves to be actuated to cause a vapor-phase of a first organometallic precursor to be flowed through the first plenum of the showerhead and into the reaction space via the first gas distribution ports, and
b) cause at least a second valve of the one or more valves to be actuated to cause a vapor-phase of a first counter-reactant to be flowed through the second plenum of the showerhead and into the reaction space via the second gas distribution ports.

2. The apparatus of claim 1, wherein the photoresist films are extreme ultra-violet photoresist films.

3. The apparatus of claim 1, wherein:
the first organometallic precursor has a formula of MₐR_{b}L_{c} where M is a metal with a high EUV absorption cross-section, R is alkyl, L is a ligand, ion, or other moiety that is reactant with the first counter-reactant, and a, b, and c are each greater than or equal to 1, and
the first counter-reactant is reactive with the first organometallic precursor so as to link two or more metal atoms of the first organometallic precursor via chemical bonding.

4. The apparatus of claim 1, wherein the metal of the first organometallic precursor has an EUV absorption cross-section absorption cross section equal to or greater than 1·10⁷ cm²/mol.

5. The apparatus of claim 3, wherein the first organometallic precursor contains a metal selected from the group consisting of: tin, bismuth, antimony, and tellurium.

6. The apparatus of claim 3, further comprising:
a first vaporizer that is fluidically connected with the first valve; and
a quantity of the first organometallic precursor located within the first vaporizer.

7. The apparatus of claim 6, further comprising:
a second vaporizer that is fluidically connected with the second valve; and
a quantity of the counter-reactant located within the second vaporizer, wherein the first counter-reactant contains a substance selected from the group consisting of: water, a peroxide, a dihydroxyl alcohol, a polyhydroxy alcohol, a fluorinated dihydroxyl alcohol, a fluorinated polyhydroxy alcohol, a fluorinated glycol, and a substance containing one or more hydroxyl moeties.

8. The apparatus of claim 3, wherein the first counter-reactant contains a substance selected from the group consisting of: water, a peroxide, a dihydroxyl alcohol, a polyhydroxy alcohol, a fluorinated dihydroxyl alcohol, a fluorinated polyhydroxy alcohol, a fluorinated glycol, and a substance containing one or more hydroxyl moeties.

9. The apparatus of claim 8, further comprising:
a second vaporizer that is fluidically connected with the second valve; and
a quantity of the counter-reactant located within the second vaporizer.

10. The apparatus of claim 1, wherein the one or more memory devices further store additional computer-executable instructions for further controlling the one or more processors to perform (a) and (b) simultaneously.

11. The apparatus of claim 1, wherein the one or more memory devices further store additional computer-executable instructions for further controlling the one or more processors to perform (a) and (b) in an alternating fashion for one or more cycles of (a) and (b).

12. The apparatus of claim 1, wherein the one or more memory devices further store additional computer-executable instructions for further controlling the one or more processors to:
c) cause at least a third valve of the one or more valves to be actuated to cause a vapor-phase of a second organometallic precursor to be flowed through the first plenum of the showerhead and into the reaction space via the first gas distribution ports, and
d) cause at least a fourth valve of the one or more valves to be actuated to cause a vapor-phase of a first counter-reactant to be flowed through the second plenum of the showerhead and into the reaction space via the second gas distribution ports, wherein the first organometallic precursor and the second organometallic precursor are different.

13. The apparatus of claim 12, further comprising:
a first vaporizer that is fluidically connected with the first valve,
a second vaporizer that is fluidically connected with the second valve,
a third vaporizer that is fluidically connected with the third valve,
a fourth vaporizer that is fluidically connected with the second valve,
a quantity of the first organometallic precursor located within the first vaporizer,
a quantity of the first counter-reactant located within the second vaporizer,
a quantity of the second organometallic precursor located within the third vaporizer, and
a quantity of the second counter-reactant located within the fourth vaporizer.

14. The apparatus of claim 13, wherein the one or more memory devices further store additional computer-executable instructions for further controlling the one or more processors to:
e) perform (a) and (b) to form a first sub-layer on a substrate supported by the wafer support, and
f) perform, subsequent to (e), (c) and (d) to form a second sub-layer on top of the first sub-layer, wherein:
the first sub-layer is a first metal oxide having a first EUV absorption cross-section,
the second sub-layer is a second metal oxide having a second EUV absorption cross-section, and
the second EUV absorption cross-section is lower than the first EUV absorption cross-section.

15. The apparatus of claim 13, wherein the one or more memory devices further store additional computer-executable instructions for further controlling the one or more processors to:
e) perform (a) and (b) multiple times and in an alternating fashion to form a first sub-layer on a substrate supported by the wafer support, and
f) perform, subsequent to (e), (c) and (d) simultaneously to form a second sub-layer on top of the first sub-layer.

16. The apparatus of claim 1, further comprising:
a first heater system for heating the showerhead;
a second heater system for heating the processing chamber; and
a top plate that is part of the wafer support and which includes a third heater system embedded therewithin, wherein the one or more memory devices further store additional computer-executable instructions for further controlling the one or more processors to control the first heater system, the second heater system, and the third heater system to cause an interior wall surface of the processing chamber to be at least 95° C. higher than an average temperature of the top plate during (a) and (b).

17. The apparatus of claim 16, wherein the one or more memory devices further store additional computer-executable instructions for further controlling the one or more processors to control the first heater system, the second heater system, and the third heater system to cause, during (a) and (b), an interior wall surface of the processing chamber to be at least 95° C. and the average temperature of the top plate to be at or below 100° C.

18. The apparatus of claim 16, wherein:
the top plate includes a plurality of mesas that protrude from a wafer support region in the top surface thereof,
the mesas are configured to support a substrate placed thereupon such that a back side gap exists between the top surface and the substrate,
the wafer support includes a plurality of gas ports within the wafer support region that are fluidically connected with the top surface, and
the one or more memory devices further store additional computer-executable instructions for further controlling the one or more processors to cause a backside cooling gas to be directed through the gas ports during (a) and (b).

19. The apparatus of claim 16, wherein:
the third heater system includes a plurality of concentric zones,
each zone has one or more resistance heater traces located therewithin, and
the one or more resistance heater traces of each zone are configured to be independently controllable by the controller.

20. The apparatus of claim 1, further comprising:
a vacuum foreline fluidically connected with the processing chamber, wherein the wafer support is fluidically interposed between the vacuum foreline and the showerhead;
a first bypass line; and
a second bypass line, wherein:
the first bypass line is fluidically connected with the vacuum foreline and with a first bypass valve of the one or more valves,
the second bypass line is fluidically connected with the vacuum foreline and with a second bypass valve of the one or more valves, and
the one or more memory devices further store additional computer-executable instructions for further controlling the one or more processors to:
actuate the one or more valves to cause the first organometallic precursor to flow through the first bypass line to the vacuum foreline prior to performing (a), and actuate the one or more valves to cause the first counter-reactant to flow through the second bypass line to the vacuum foreline prior to performing (b).
